(19) United States
(12) Patent Application Publication
(10) Pub. No.: US 2025/0220902 A1
(43) Pub. Date: Jul. 3, 2025

(54) CONSOLIDATION OF STAIRCASE AREA ETCH AND CMOS CONTACT AREA ETCH IN 3D NAND

(71) Applicant: Intel NDTM US LLC, Santa Clara, CA (US)

(72) Inventors: Liu Liu, Dalian City, Liaoning (CN); Chuan Sun, Dalian City, Liaoning (CN); Jianze Zhao, Dalian City, Liaoning (CN)

(21) Appl. No.: 18/851,045

(22) PCT Filed: Apr. 27, 2022
(86) PCT No.: PCT/CN2022/089638

§ 371 Date: Sep. 25, 2024

(51) Int. Cl. H10B 43/27; G11C 5/02; G11C 5/06; H10B 43/35

(52) U.S. Cl. CPC H10B 43/27; G11C 5/025; G11C 5/063; H10B 43/35

(57) ABSTRACT

Systems, apparatuses, and methods may provide for technology that simultaneously forms staircase areas and CMOS (complementary metal-oxide-semiconductor) contact areas in three-dimensional (3D) NAND memory. A 3D NAND memory includes a first CMOS contact area and a first staircase area. The first CMOS contact area is formed through a plurality of sequential chops. The first staircase area is formed through a plurality of sequential staircase chops. The first CMOS contact area is formed through the plurality of sequential chops being performed simultaneous to the plurality of sequential staircase chops.

### CROSS REFERENCE TO RELATED APPLICATIONS

The present application is a U.S. National Phase patent application, which claims the benefit of priority to International Patent Application No. PCT/CN2022/089638 filed on Apr. 27, 2022.

### TECHNICAL FIELD

Embodiments generally relate to memory structures. More particularly, embodiments relate to staircase area and CMOS (complementary metal-oxide-semiconductor) contact area formation in memory structures.

### BACKGROUND

Three-dimensional (3D) NAND technologies are commonly used to create nonvolatile (NV) storage devices, such as solid state drives (SSDs). Reference to 3D NAND can more specifically refer to NAND flash.

NAND-type flash memory (“NAND memory”) may be organized into multiple cells, with each cell containing one or more bits of data and being accessible through an array of bit lines (columns) and word lines (rows). With 3D NAND processes, the storage array is often created with the word lines (WL) in a staircase structure, with vertical connector pillars connecting a top connection layer to the word lines.

Increased 3D NAND densities are achieved with smaller process geometries and feature spacing. With the increase of number of tiers or word lines in 3D NAND in every generation, the number of WL contacts is also going up, requiring more routing paths to hook up the word line contacts to corresponding complementary metal-oxide-semiconductor (CMOS) devices.

In CMOS under array (CUA) architecture types used in 3D NAND, there is a need to form staircase area contacts (MLC) and CMOS area contacts (CON3 in this case). These contacts are formed by high aspect ratio etches that are >10 um deep, which can be quite costly.

### BRIEF DESCRIPTION OF THE DRAWINGS

The various advantages of the embodiments will become apparent to one skilled in the art by reading the following specification and appended claims, and by referencing the following drawings, in which:

FIG. 1 is a block diagram of an example of a multi-deck non-volatile memory device according to an embodiment;

FIG. 2 illustrates an example side view diagram of a memory die according to an embodiment;

FIGS. 3-8 illustrate an example side view diagram of an example memory device according to an embodiment at various stages of formation;

FIG. 9 is a flowchart of an example of another method of forming a memory device according to an embodiment;

FIG. 10 is an illustration of an example of a semiconductor package apparatus according to an embodiment; and

FIG. 11 is a block diagram of an example of a performance-enhanced computing system according to an embodiment.

### DESCRIPTION OF EMBODIMENTS

In existing staircase cell floor plans for 3D NAND, CMOS contact areas (Con3) and staircase areas (e.g., for word line contacts) are etched open separately. The staircase contacts (MLC) are placed in a staircase (SC) region and string driver CMOS device contacts are placed in CMOS contact areas (e.g., a Through Array Via (TAV) region). In 3D NAND CMOS under array (CUA) architecture, these contacts are formed by high aspect ratio etches that are often greater than 10 um deep, which can be quite costly. Embodiments consolidate the two etches into one for significant cost savings per wafer.

As will be described in greater detail below, systems, apparatuses, and methods described herein may provide for technology that simultaneously forms staircase areas and CMOS contact areas in three-dimensional (3D) NAND memory. A 3D NAND memory includes a first complementary metal-oxide-semiconductor contact area and a first staircase area. The first complementary metal-oxide-semiconductor contact area is formed through a plurality of sequential chops. The first staircase area is formed through a plurality of sequential staircase chops. The first complementary metal-oxide-semiconductor contact area is formed through the plurality of sequential chops being performed simultaneous to the plurality of sequential staircase chops.

Advantageously, some of the techniques described herein consolidate the two etches into one etch simultaneous etch, which will often result in a cost savings of more than $100 per wafer. Additionally, or alternatively, complementary metal-oxide-semiconductor contact area formation will be inside pure oxide, which advantageously eliminates potential liner damage or staircase contact (MLC) interaction issues.

As will be described in greater detail below, some of the techniques described herein consolidate a CMOS contact areas etch into an MLC etch (e.g., staircase area). For example, a staircase etch and gap fill is used to simultaneously remove an oxide/polysilicon stack (OPOP) and dummy pillars in the CMOS contact areas region so that no separate etch and gap fill cost would be induced.

In some of the techniques described herein, the staircase etch is relocated to after all three deck oxide/polysilicon stack (OPOP) and cell segments. In the staircase etch segment, CMOS contact areas are opened simultaneous to all staircase chop layers. In these chop layers, the etch processes will etch both OPOP in the staircase region as well as dummy pillars in the CMOS contact areas. In some examples, an etch stop nitride layer is then deposited after the staircase etch process is finished. In some implementations, an additional chop layer is introduced to etch away stop nitride, remaining dummy pillar materials, and select gate source (SGS) in the CMOS contact areas, with array and staircase areas being protected by photo resist. This additional chop stops on the Source Plate (SRC) (e.g., 45 WSix). After such a final CMOS contact area chop, oxide is deposited in the staircase and CMOS contact areas to fill these regions, followed by an oxide Chemical mechanical polishing/planarization (CMP). Finally, CMOS contacts, Common Source (SRC) contacts, and staircase word line (WL) contacts are formed together by a single etch and metal fill. Because some of the techniques described herein extend the staircase etch into the CMOS contact area, there will be a clearly visible nitride layer coated around the boundary of the CON3 clusters.

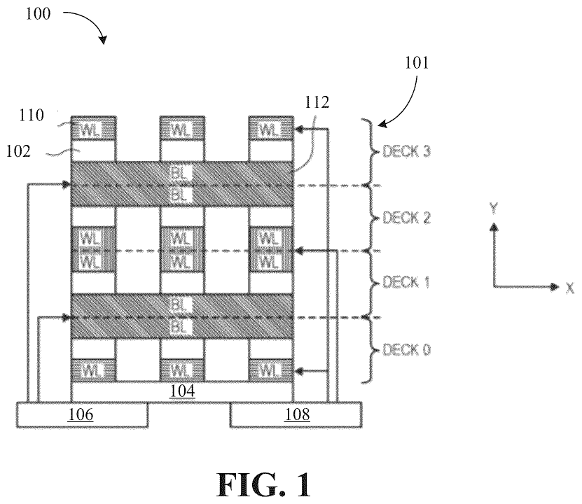

FIG. 1 is a simplified block diagram of an example of a memory device 100 according to an embodiment. As illustrated, the memory device 100 is a multi-deck non-volatile memory device including a plurality of decks 101 (e.g., Deck 0, Deck 1, Deck 2, and Deck 3, or the like).

In some implementations, each of the decks 101 may include an array of memory cells 102 with conductive access lines (e.g., word lines 110 and bitlines 112). For example, the memory cells 102 may include a material capable of being in two or more stable states to store a logic value. In one example, the memory cells 102 may include a phase change material, a chalcogenide material, the like, or combinations thereof. However, any suitable storage material may be utilized. The word lines 110 and bitlines 112 may be patterned so that the word lines 110 are orthogonal to the bitlines 112, creating a grid pattern or “cross-points.” A cross-point is an intersection between a bitline, a word line, and active material(s) (e.g., a selector and/or a storage material). A memory cell 102 may be located at the intersection of a bitline 112 and a word line 110. Accordingly, one or more of the decks 101 may include a crosspoint array of non-volatile memory cells, where each of the memory cells may include a material capable of being in two or more stable states to store a logic value.

As illustrated, an electrically isolating material 104 may separate the conductive access lines (e.g., word lines 110 and bitlines 112) of the bottom deck (e.g., deck 0) from bitline sockets 106 and word line sockets 108. For example, the memory cells 102 may be coupled with access and control circuitry for operation of the three-dimensional memory device 100 via the bitline sockets 106 and the word line sockets 108.

Examples of multi-deck or multi-layer memory architectures include multi-deck crosspoint memory and 3D NAND memory. Different memory technologies have adopted different terminology. For example, a deck in a crosspoint memory device typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2X-layer NAND device). The term “deck” will be used throughout this disclosure to describe a layer, a tier, or a similar portion of a three-dimensional memory.

The memory device 100 may include non-volatile memory and/or volatile memory. Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices, such as a three-dimensional (3D) crosspoint memory device, or other byte addressable write-in-place nonvolatile memory devices. In one embodiment, the storage device may be or may include memory devices that use silicon-oxide-nitride-oxide-silicon (SONOS) memory, electrically erasable programmable read-only memory (EEPROM), chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory. The term “storage device” may refer to the die itself and/or to a packaged memory product. In some embodiments, 3D crosspoint memory may comprise a transistor-less stackable cross point architecture in which memory cells sit at the intersection of word lines and bit lines and are individually addressable and in which bit storage is based on a change in bulk resistance. In particular embodiments, a memory module with non-volatile memory may comply with one or more standards promulgated by the Joint Electron Device Engineering Council (JEDEC), such as JESD235, JESD218, JESD219, JESD220-1, JESD223B, JESD223-1, or other suitable standard (the JEDEC standards cited herein are available at jedec.org).

Volatile memory is a storage medium that requires power to maintain the state of data stored by the medium. Examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of the memory modules complies with a standard promulgated by JEDEC, such as JESD79F for Double Data Rate (DDR) SDRAM, JESD79-2F for DDR2 SDRAM, JESD79-3F for DDR3 SDRAM, or JESD79-4A for DDR4 SDRAM (these standards are available at jedec.org). Such standards (and similar standards) may be referred to as DDR-based standards and communication interfaces of the storage devices that implement such standards may be referred to as DDR-based interfaces.

As will be described in greater detail below, systems, apparatuses and methods of some implementations herein provide for technology that simultaneously forms staircase areas and CMOS contact areas in three-dimensional (3D) NAND memory.

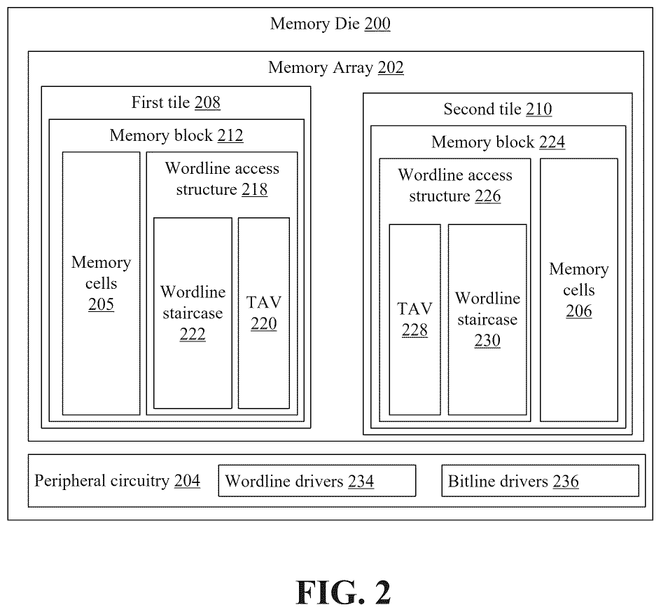

FIG. 2 illustrates a simplified example side view diagram of a memory die 200, consistent with one embodiment of the present disclosure. The memory die 200 includes a 3D flash memory architecture and utilizes a word line bridge to share word line access structures between two tiles of a memory array, according to one embodiment.

The memory die 200 includes a memory array 202 and peripheral circuitry 204, according to one embodiment. The memory array 202 includes memory cells 205 and memory cells 206 that are accessed (e.g., read/write) with the peripheral circuitry 204, according to one embodiment. The peripheral circuitry 204 is fabricated at least partially under the memory array 202 in the memory die 200, for example, using CMOS under the array fabrication techniques, according to one embodiment.

The memory array 202 is segmented into a first tile 208 and a second tile 210, according to one embodiment. Although two tiles are illustrated and described the memory array 202 may be segmented into 10's or 100's of tiles to facilitate access and operation of the memory array 202, according to one embodiment. The first tile 208 includes a memory block 212, which includes the memory cells 205 and word line access structures 218, according to one embodiment. The word line access structures 218 include through array vias 220 and a word line staircase 222, according to one embodiment. The through array vias 220 connect word lines for the memory cells 205 to the peripheral circuitry 204, under the memory array 202, according to one embodiment. The word line staircase 222 represents a word line staircase structure that may be used to connect the word lines of the memory cells 205 to metal contacts for connection to upper metal levels, according to one embodiment. The word line access structures 218 are illustrated disproportionately large in comparison to the memory cells 205 for illustration purposes. In practice, the memory cells 205 may occupy a significantly larger area in the memory array that the word line access structures 218, according to one embodiment.

The second tile 210 includes a memory block 224, which includes the memory cells 206 and word line access structures 226, according to one embodiment. The word line access structures 226 include through array vias 228 and a word line staircase 230, according to one embodiment. The through array vias 228 pass through the memory block 224 to couple upper metal levels to the peripheral circuitry 204, according to one embodiment. The word line staircase 230 provides landings and/or a structure to which metal contacts connect the word lines of the memory cells 206 to upper metal levels that are on top of or above the memory array 202, according to one embodiment.

The peripheral circuitry 204 includes word line drivers 234 and bitline drivers 236 that drive word lines and bitlines for the memory array 202, according to one embodiment.

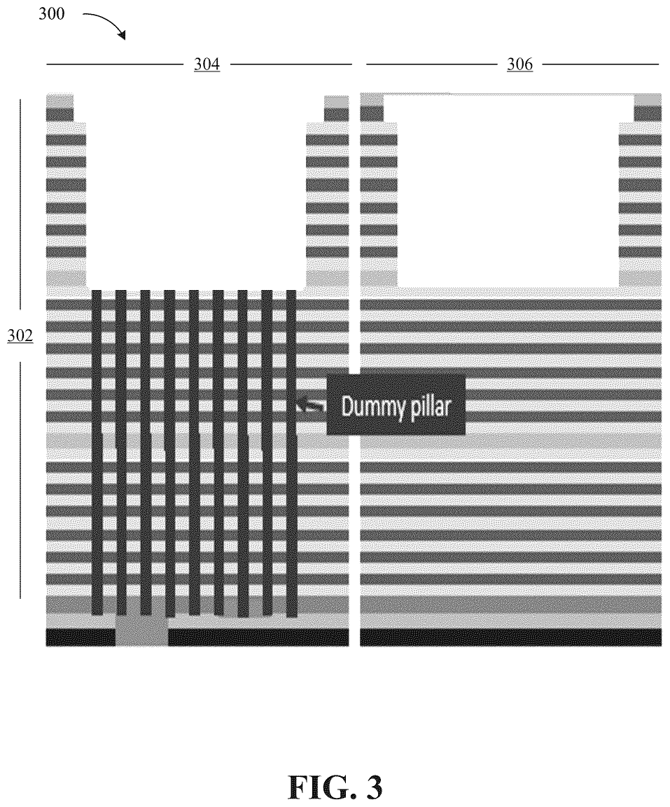

FIGS. 3-8 illustrate an example side view diagram of an example memory device 300 according to an embodiment at various stages of formation.

As illustrated in FIG. 3, the memory device 300 includes a previously formed multi-deck structure 302. A first chop is performed to the multi-deck structure 302 simultaneously in both a first complementary metal-oxide-semiconductor contact area 304 and a first staircase area 306. The first chop removes a first portion of the multi-deck structure 302.

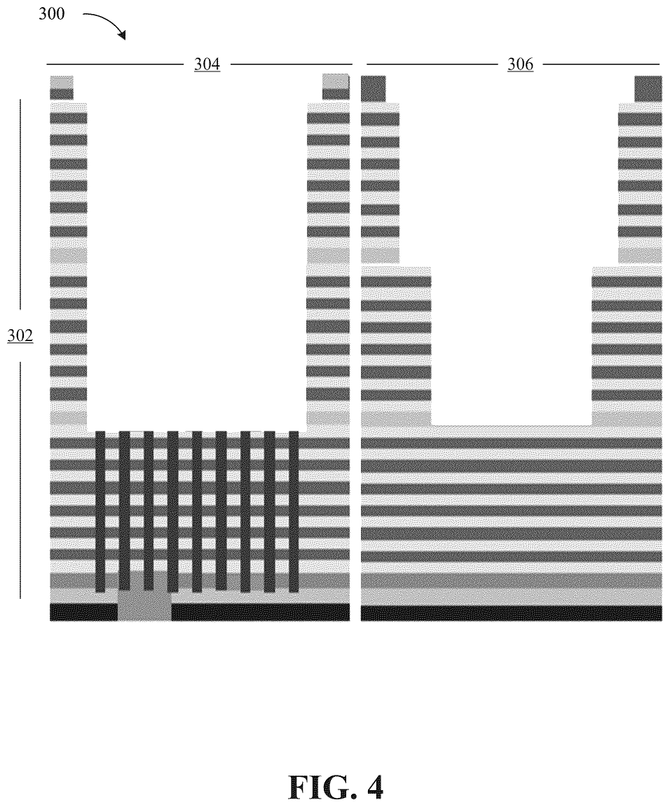

As illustrated in FIG. 4, a second chop is performed to the multi-deck structure 302 simultaneously in both the first complementary metal-oxide-semiconductor contact area 304 and the first staircase area 306. The second chop removes a second portion of the multi-deck structure 302.

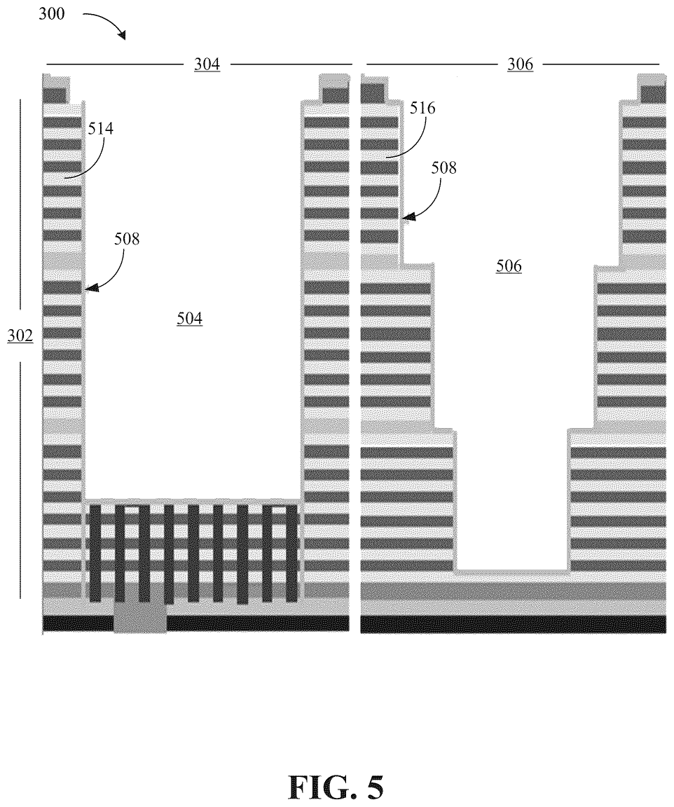

As illustrated in FIG. 5, a third chop is performed to the multi-deck structure 302 simultaneously in both the first complementary metal-oxide-semiconductor contact area 304 and the first staircase area 306. The third chop removes a third portion of the multi-deck structure 302.

It will be appreciated that each chop is associated with an individual staircase, accordingly more or fewer chops may be performed depending on the number of stair levels included in the first staircase area 306.

In some examples, a nitride stop layer 508 is deposited on one or more staircase walls 516 of the first staircase area 306 and on one or more side walls 514 of the first complementary metal-oxide-semiconductor contact area. In some implementations, the nitride stop layer 508 is deposited after completion of the staircase opening 506.

As seen in FIGS. 3-5, a plurality of sequential chops are performed to the multi-deck structure 302 to form a central opening 504 of the first complementary metal-oxide-semiconductor contact area 304. Likewise, a plurality of sequential staircase chops are performed to the multi-deck structure 302 to form a staircase opening 506 of the first staircase area 306. As described above, the plurality of sequential chops to form the central opening 504 of the first complementary metal-oxide-semiconductor contact area 304 is performed simultaneous to the plurality of sequential staircase chops to form the staircase opening 506 of the first staircase area 306.

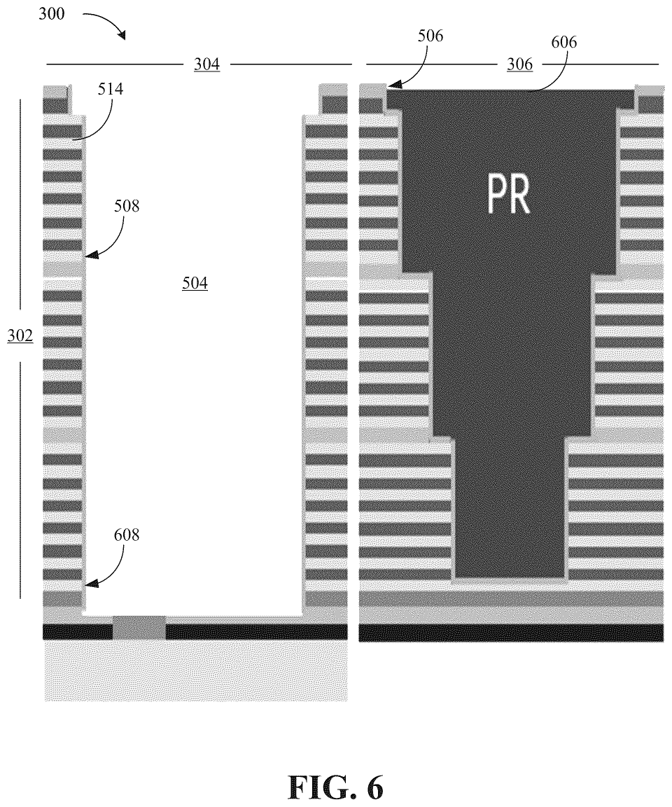

As illustrated in FIG. 6, an additional chop is performed to remove residual material 604 (see, FIG. 5) in the central opening 504 of the first complementary metal-oxide-semiconductor contact area 304. At this time, the staircase opening 506 of the first staircase area 306 is protected by a photoresist fill 606.

In some implementations, an additional nitride stop layer 608 is deposited on the one or more side walls 514 of the first complementary metal-oxide-semiconductor contact area 304. The additional nitride stop layer 608 is deposited after removal of the residual material 604 (see, FIG. 5) in the central opening 504.

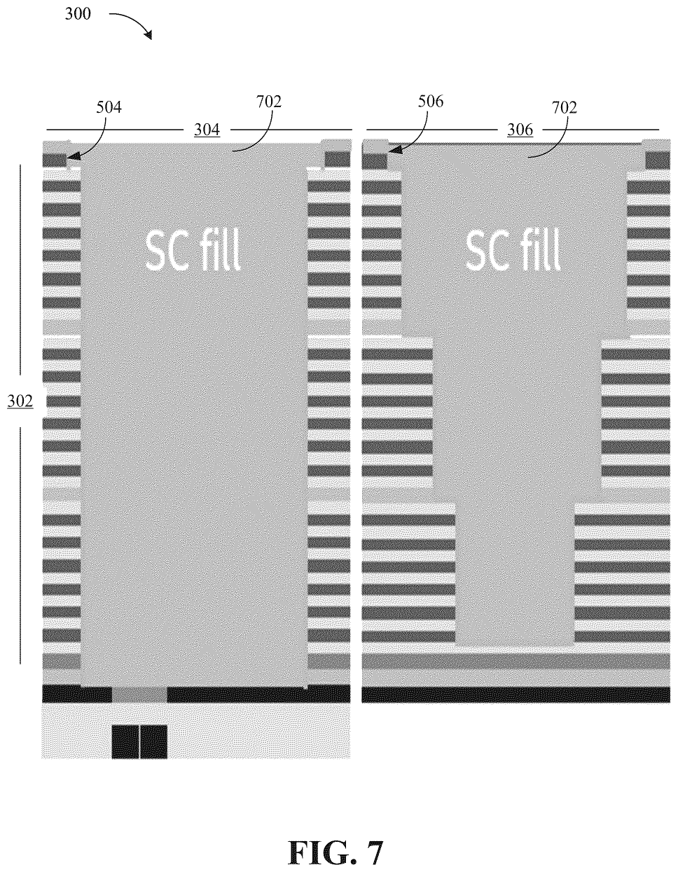

As illustrated in FIG. 7, a gap fill 702 and a chemical mechanical polish are performed for the central opening 504 and the staircase opening 506 simultaneously.

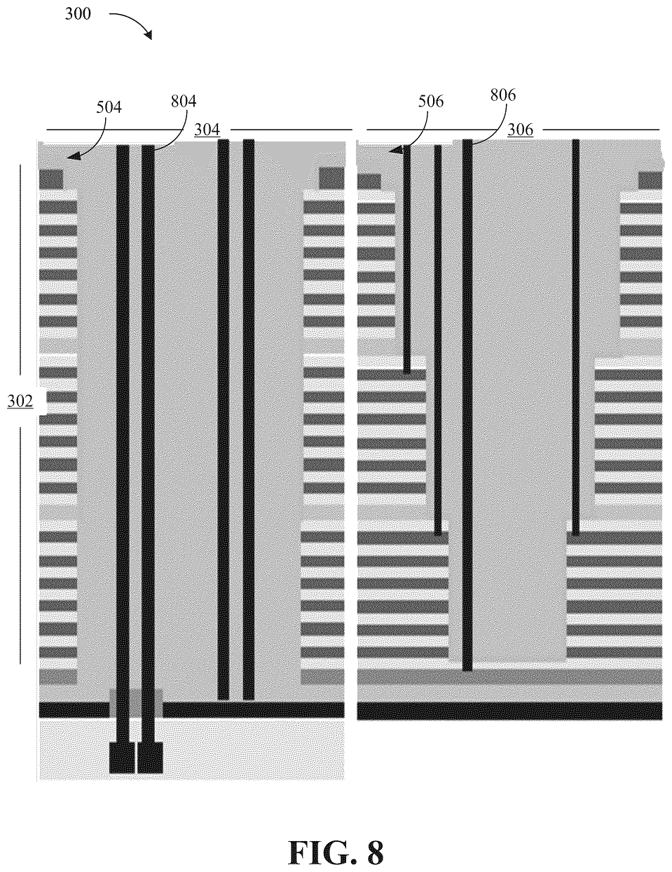

As illustrated in FIG. 8, a contact etch and fill is performed for the first complementary metal-oxide-semiconductor contact area 304 and the first staircase area 306 simultaneously.

In some examples, contacts 804 formed in the first complementary metal-oxide-semiconductor contact area 304 and word line contacts 806 the first staircase area 306 are formed simultaneously.

As formed the memory device 300 includes a memory array (see, e.g., the memory array 202 of FIG. 2) and a memory block (see, e.g., the memory block 212 of FIG. 2) coupled to the memory array in some implementations. For example, the memory block includes the first complementary metal-oxide-semiconductor contact area 304, where the first complementary metal-oxide-semiconductor contact area 304 has been formed through a plurality of sequential chops. The memory block further includes the first staircase area 306, where the first staircase area 306 has been formed through a plurality of sequential staircase chops. Advantageously, the first complementary metal-oxide-semiconductor contact area 304 has been formed through the plurality of sequential chops performed simultaneous to the plurality of sequential staircase chops.

In some implementations, the first complementary metal-oxide-semiconductor contact area 304 includes on the one or more side walls 514 defining the central opening 504. The one or more side walls 514 have the nitride stop layer 508 deposited thereon. Similarly, the first staircase area 306 includes the one or more staircase walls 516 defining the staircase opening 506, where the one or more staircase walls 516 have the nitride stop layer 508 deposited thereon. Additionally, the one or more side walls 514 have the nitride stop layer 508 deposited thereon in a plurality of separately performed depositions (e.g., including the additional nitride stop layer 614).

In some implementations, the memory device is a three-dimensional (3D) NAND memory.

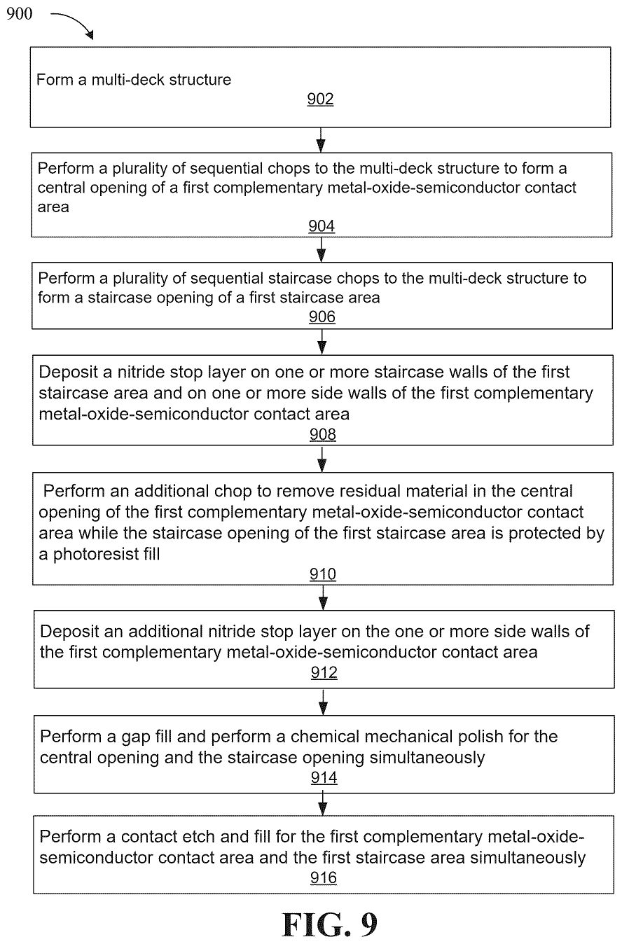

Additional details regarding memory device 300 are discussed below with respect to FIG. 9.

FIG. 9 is a flowchart of an example of a method 900 of forming a memory device according to an embodiment. The method 900 may generally be implemented to form a memory device, such as, for example, the memory device 300 (e.g., see FIGS. 3-8), already discussed.

Illustrated processing block 902 provides for forming a multi-deck structure. For example, a three deck oxide/polysilicon stack (OPOP) multi-deck structure, or the like, may be formed.

Illustrated processing block 904 provides for performing a plurality of sequential chops to the multi-deck structure. For example, a plurality of sequential chops may be performed on the multi-deck structure to form a central opening of a first complementary metal-oxide-semiconductor contact area.

Illustrated processing block 906 provides for performing a plurality of sequential staircase chops to the multi-deck structure.

For example, a plurality of sequential staircase chops may be performed on the multi-deck structure to form a staircase opening of a first staircase area.

Advantageously, the plurality of sequential chops to form the central opening of the first complementary metal-oxide-semiconductor contact area in processing block 904 is performed simultaneous to the plurality of sequential staircase chops in processing block 906, for example.

Illustrated processing block 908 provides for depositing a nitride stop layer on one or more staircase walls of the first staircase area and on one or more side walls of the first complementary metal-oxide-semiconductor contact area. For example, the nitride stop layer is deposited after completion of the staircase opening.

Illustrated processing block 910 provides for performing an additional chop to remove residual material in the central opening of the first complementary metal-oxide-semiconductor contact area. For example, an additional chop may be performed to remove residual material in the central opening of the first complementary metal-oxide-semiconductor contact area while the staircase opening of the first staircase area is protected by a photoresist fill.

Illustrated processing block 912 provides for depositing an additional nitride stop layer on the one or more side walls of the first complementary metal-oxide-semiconductor contact area. For example, the additional nitride stop layer is deposited after removal of the residual material in the central opening.

Illustrated processing block 914 provides for performing a gap fill and a chemical mechanical polish. For example, a gap fill and a chemical mechanical polish may be performed for the central opening and the staircase opening simultaneously.

Illustrated processing block 916 provides for performing a contact etch and fill. For example, a contact etch and fill may be performed for the first complementary metal-oxide-semiconductor contact area and the first staircase area simultaneously.

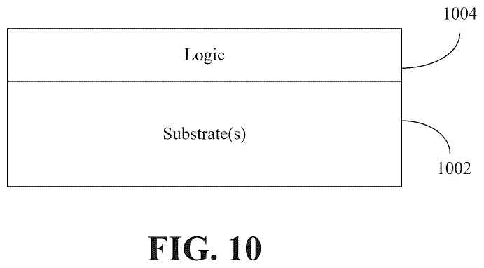

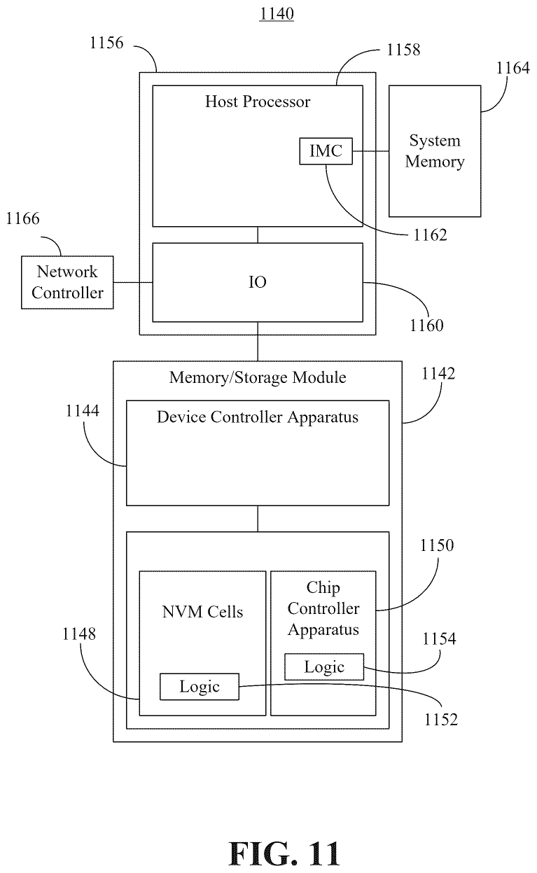

Additional details regarding the various implementations of method 900 are discussed below with regard to FIGS. 10 and 11.

FIG. 10 shows a semiconductor apparatus 1000 (e.g., chip, die, and/or package). The illustrated apparatus 1000 includes one or more substrates 1002 (e.g., silicon, sapphire, gallium arsenide) and logic 1004 (e.g., transistor array and other integrated circuit/IC components) coupled to the substrate(s) 1002. In an embodiment, the logic 1004 implements one or more aspects of the memory device 300 (FIGS. 3-8) already discussed.

In one example, the logic 1004 includes transistor channel regions that are positioned (e.g., embedded) within the substrate(s) 1002. Thus, the interface between the logic 1004 and the substrate 1002 may not be an abrupt junction. The logic 1004 may also be considered to include an epitaxial layer that is grown on an initial wafer of the substrate 1002.

Turning now to FIG. 11, a performance-enhanced computing system 1140 is shown. In the illustrated example, a solid state drive (SSD) 1142 includes a device controller apparatus 1144 that is coupled to a NAND 1146. The illustrated NAND 1146 includes a memory device 1148 having a set of multi-level NVM cells and logic 1152 (e.g., transistor array and other integrated circuit/IC components coupled to one or more substrates containing silicon, sapphire and/or gallium arsenide), and a chip controller apparatus 1150 that includes logic 1154. The logic 1154 may include one or more of configurable or fixed-functionality hardware.

The illustrated system 1140 also includes a system on chip (SoC) 1156 having a host processor 1158 (e.g., central processing unit/CPU) and an input/output (I/O) module 1160. The host processor 1158 may include an integrated memory controller 1162 (IMC) that communicates with system memory 1164 (e.g., RAM dual inline memory modules/DIMMs). The illustrated IO module 1160 is coupled to the SSD 1142 as well as other system components such as a network controller 1166.

In some embodiments, the NAND 1146 implements one or more aspects of the memory device 300 (FIGS. 3-8) already discussed. For example, the NAND 1146 is implementable as a multi-deck non-volatile memory structure comprising a plurality of decks coupled to the device controller apparatus 1144 (e.g., a memory controller).

### Additional Notes and Examples

Example 1 includes a memory device comprising a memory array, and a memory block coupled to the memory array. The memory block comprising a first complementary metal-oxide-semiconductor contact area, wherein the first complementary metal-oxide-semiconductor contact area has been formed through a plurality of sequential chops.

Example 2 includes the memory device of Example 1, the memory block further comprising a first staircase area, wherein the first staircase area has been formed through a plurality of sequential staircase chops, and wherein the first complementary metal-oxide-semiconductor contact area has been formed through the plurality of sequential chops performed simultaneous to the plurality of sequential staircase chops.

Example 3 includes the memory device of one of Examples 1 to 2, wherein the first complementary metal-oxide-semiconductor contact area includes one or more side walls defining a central opening, and wherein the one or more side walls have a nitride stop layer deposited thereon.

Example 4 includes the memory device of Example 3, wherein the first staircase area includes one or more staircase walls defining a staircase opening, and wherein the one or more staircase walls have the nitride stop layer deposited thereon.

Example 5 includes the memory device of one of Examples 3 to 4, wherein the one or more side walls have the nitride stop layer deposited thereon in a plurality of separately performed depositions.

Example 6 includes the memory device of one of Examples 2 to 5, wherein contacts formed in the first complementary metal-oxide-semiconductor contact area and the first staircase area were formed simultaneously.

Example 7 includes the memory device of one of Examples 1 to 6, wherein the memory device is a three-dimensional (3D) NAND memory.

Example 8 includes a solid state drive (SSD) comprising a memory controller, and a memory device coupled to the memory controller. The memory device comprising a memory array, and a memory block coupled to the memory array. The memory block comprising a first complementary metal-oxide-semiconductor contact area, wherein the first complementary metal-oxide-semiconductor contact area has been formed through a plurality of sequential chops.

Example 9 includes the solid state drive (SSD) of Example 8, the memory block further comprising a first staircase area, wherein the first staircase area has been formed through a plurality of sequential staircase chops, and wherein the first complementary metal-oxide-semiconductor contact area has been formed through the plurality of sequential chops performed simultaneous to the plurality of sequential staircase chops.

Example 10 includes the solid state drive (SSD) of one of Examples 8 to 9, wherein the first complementary metal-oxide-semiconductor contact area includes one or more side walls defining a central opening, and wherein the one or more side walls have a nitride stop layer deposited thereon.

Example 11 includes the solid state drive (SSD) of Example 10, wherein the first staircase area includes one or more staircase walls defining a staircase opening, and wherein the one or more staircase walls have the nitride stop layer deposited thereon.

Example 12 includes the solid state drive (SSD) of one of Examples 10 to 11, wherein the one or more side walls have the nitride stop layer deposited thereon in a plurality of separately performed depositions.

Example 13 includes the solid state drive (SSD) of one of Examples 9 to 12, wherein contacts formed in the first complementary metal-oxide-semiconductor contact area and the first staircase area were formed simultaneously.

Example 14 includes a method comprising forming a multi-deck structure, and performing a plurality of sequential chops to the multi-deck structure to form a central opening of a first complementary metal-oxide-semiconductor contact area.

Example 15 includes the method of Example 14, further comprising performing a plurality of sequential staircase chops to the multi-deck structure to form a staircase opening of a first staircase area, wherein the plurality of sequential chops is performed simultaneous to the plurality of sequential staircase chops.

Example 16 includes the method of Example 15, further comprising depositing a nitride stop layer on one or more staircase walls of the first staircase area and on one or more side walls of the first complementary metal-oxide-semiconductor contact area, wherein the nitride stop layer is deposited after completion of the staircase opening.

Example 17 includes the method of one of Examples 15 to 16, further comprising performing an additional chop to remove residual material in the central opening of the first complementary metal-oxide-semiconductor contact area while the staircase opening of the first staircase area is protected by a photoresist fill.

Example 18 includes the method of Example 17, further comprising depositing an additional nitride stop layer on the one or more side walls of the first complementary metal-oxide-semiconductor contact area, wherein the additional nitride stop layer is deposited after removal of the residual material in the central opening.

Example 19 includes the method of one of Examples 15 to 18, further comprising performing a gap fill and performing a chemical mechanical polish for the central opening and the staircase opening simultaneously.

Example 20 includes the method of one of Examples 15 to 18, further comprising performing a contact etch and fill for the first complementary metal-oxide-semiconductor contact area and the first staircase area simultaneously.

Example 21 includes a machine-readable storage comprising machine-readable instructions, which when executed, implement a method or realize an apparatus as claimed in any preceding claim.

Example 22 includes an apparatus comprising means for performing the method of any one of Examples 15 to 20.

Advantageously, some of the technology described herein consolidate the two etches into one etch simultaneous etch, which will often result in a cost savings of more than $100 per wafer. Additionally, or alternatively, complementary metal-oxide-semiconductor contact area formation will be inside pure oxide, which advantageously eliminates potential liner damage or staircase contact (MLC) interaction issues.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A memory device comprising:
a memory array; and
a memory block coupled to the memory array, the memory block comprising:
a first complementary metal-oxide-semiconductor contact area, wherein the first complementary metal-oxide-semiconductor contact area has been formed through a plurality of sequential chops.

2. The memory device of claim 1, the memory block further comprising:
a first staircase area, wherein the first staircase area has been formed through a plurality of sequential staircase chops, and wherein the first complementary metal-oxide-semiconductor contact area has been formed through the plurality of sequential chops performed simultaneous to the plurality of sequential staircase chops.

3. The memory device of claim 1, wherein the first complementary metal-oxide-semiconductor contact area includes one or more side walls defining a central opening, and wherein the one or more side walls have a nitride stop layer deposited thereon.

4. The memory device of claim 3, wherein the first staircase area includes one or more staircase walls defining a staircase opening, and wherein the one or more staircase walls have the nitride stop layer deposited thereon.

5. The memory device of claim 3, wherein the one or more side walls have the nitride stop layer deposited thereon in a plurality of separately performed depositions.

6. The memory device of claim 2, wherein contacts formed in the first complementary metal-oxide-semiconductor contact area and the first staircase area were formed simultaneously.

7. The memory device of claim 1, wherein the memory device is a three-dimensional (3D) NAND memory.

8. A solid state drive (SSD) comprising:
a memory controller; and
a memory device coupled to the memory controller, the memory device comprising:
a memory array; and
a memory block coupled to the memory array, the memory block comprising:
a first complementary metal-oxide-semiconductor contact area, wherein the first complementary metal-oxide-semiconductor contact area has been formed through a plurality of sequential chops.

9. The solid state drive (SSD) of claim 8, the memory block further comprising:
a first staircase area, wherein the first staircase area has been formed through a plurality of sequential staircase chops, and wherein the first complementary metal-oxide-semiconductor contact area has been formed through the plurality of sequential chops performed simultaneous to the plurality of sequential staircase chops.

10. The solid state drive (SSD) of claim 8, wherein the first complementary metal-oxide-semiconductor contact area includes one or more side walls defining a central opening, and wherein the one or more side walls have a nitride stop layer deposited thereon.

11. The solid state drive (SSD) of claim 10, wherein the first staircase area includes one or more staircase walls defining a staircase opening, and wherein the one or more staircase walls have the nitride stop layer deposited thereon.

12. The solid state drive (SSD) of claim 10, wherein the one or more side walls have the nitride stop layer deposited thereon in a plurality of separately performed depositions.

13. The solid state drive (SSD) of claim 9, wherein contacts formed in the first complementary metal-oxide-semiconductor contact area and the first staircase area were formed simultaneously.

14. A method comprising:
forming a multi-deck structure; and
performing a plurality of sequential chops to the multi-deck structure to form a central opening of a first complementary metal-oxide-semiconductor contact area.

15. The method of claim 14, further comprising:
performing a plurality of sequential staircase chops to the multi-deck structure to form a staircase opening of a first staircase area, wherein the plurality of sequential chops is performed simultaneous to the plurality of sequential staircase chops.

16. The method of claim 15, further comprising:
depositing a nitride stop layer on one or more staircase walls of the first staircase area and on one or more side walls of the first complementary metal-oxide-semiconductor contact area, wherein the nitride stop layer is deposited after completion of the staircase opening.

17. The method of claim 16, further comprising:
performing an additional chop to remove residual material in the central opening of the first complementary metal-oxide-semiconductor contact area while the staircase opening of the first staircase area is protected by a photoresist fill.

18. The method of claim 17, further comprising:
depositing an additional nitride stop layer on the one or more side walls of the first complementary metal-oxide-semiconductor contact area, wherein the additional nitride stop layer is deposited after removal of the residual material in the central opening.

19. The method of claim 18, further comprising:
performing a gap fill and performing a chemical mechanical polish for the central opening and the staircase opening simultaneously.

20. The method of claim 19, further comprising:
performing a contact etch and fill for the first complementary metal-oxide-semiconductor contact area and the first staircase area simultaneously.
